(19) United States
(12) Patent Application Publication
(10) Pub. No.: US 2008/0001656 A1
(43) Pub. Date: Jan. 3, 2008

(54) SEMICONDUCTOR INTEGRATED CIRCUIT

(76) Inventor: Yoshiaki TAKEUCHI, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 11/770,188

(22) Filed: Jun. 28, 2007

(30) Foreign Application Priority Data
Jun. 30, 2006 (JP) 2006-182449

(51) Int. Cl. G11C 5/14; G05F 1/59

(52) U.S. Cl. 327/544

(57) ABSTRACT

A semiconductor integrated circuit of the invention comprises an internal power supply voltage down circuit which steps down a first external power supply voltage to produce an internal power supply voltage, an input circuit to which the internal power supply voltage is supplied, an internal circuit to which the first external power supply voltage is supplied and which is connected to the input circuit, and an output circuit to which a second external power supply voltage differing from the first external power supply voltage is supplied and which is connected to the internal circuit. The second external power supply voltage is separated from the first external power supply voltage and is lower than the first external power supply voltage.

### CROSS-REFERENCE TO RELATED APPLICATIONS

This application is based upon and claims the benefit of priority from prior Japanese Patent Application No. 2006-182449, filed Jun. 30, 2006, the entire contents of which are incorporated herein by reference.

### BACKGROUND OF THE INVENTION

1. Field of the Invention

This invention relates to a semiconductor integrated circuit. More particularly, this invention relates to an input first stage of a semiconductor integrated circuit.

2. Description of the Related Art

In recent years, portable electronics devices have been designed to consume less and less power.

For example, mobile-phones and mobile terminals into which a semiconductor memory, such as a NAND flash memory, has been incorporated have been required to have low power consumption.

With this backdrop, the technique for decreasing the power consumption of a semiconductor integrated circuit including a semiconductor memory has been considered (e.g., refer to U.S. Pat. No. 5,966,045).

When the power supply voltage is lowered to reduce the power consumption of a semiconductor integrated circuit, this causes a problem: the response speed of the driving circuit included in the semiconductor integrated circuit gets slower.

To avoid this problem, some semiconductor integrated circuit has two or more external power terminals and separately includes a semiconductor integrated circuit power supply VCC and an input/output circuit power supply voltage VCCQ to set separate desired voltages.

As an example, the power supply voltage VCCQ is supplied from a common power supply to an input buffer circuit and an output buffer circuit which serve as the input and output circuits.

When the power supply voltage VCCQ is shared by the input and output buffer circuits as described above, the input buffer circuit is directly affected by the effect of noise caused by the operation of the output buffer circuit.

As a result, the threshold voltage of the input buffer circuit fluctuates, which leads to an erroneous determination of a signal level made on the basis of a high-level input voltage (VIH) and a low-level input voltage (VIL) determined in the circuit design specification.

To avoid the above problem, there is a method of providing an input buffer circuit power supply voltage and an output buffer circuit power supply voltage separately to produce a power supply voltage VCCQ1 for the input buffer circuit only and a power supply voltage VCCQ2 for the output buffer circuit only.

In this case, however, the number of power supply pads and power wires increases.

### BRIEF SUMMARY OF THE INVENTION

According to an aspect of the present invention, there is provided a semiconductor integrated circuit comprising: an internal power supply voltage down circuit which steps down a first external power supply voltage to produce an internal power supply voltage;

an input circuit to which the internal power supply voltage is supplied; an internal circuit to which the first external power supply voltage is supplied and which is connected to the input circuit; and an output circuit to which a second external power supply voltage differing from the first external power supply voltage is supplied and which is connected to the internal circuit, wherein the first and second external power supply voltages are separated from each other and the second external power supply voltage is lower than the first external power supply voltage.

According to another aspect of the present invention, there is provided a semiconductor integrated circuit comprising: a first internal power supply voltage down circuit which steps down a first external power supply voltage to produce a first internal power supply voltage; an input circuit to which the first internal power supply voltage is supplied; a second internal power supply voltage down circuit which steps down the first external power supply voltage to produce a second internal power supply voltage; an internal circuit to which the second internal power supply voltage is supplied and which is connected to the input circuit; and an output circuit to which a second external power supply voltage differing from the first external power supply voltage is supplied and which is connected to the internal circuit, wherein the first and second external power supply voltages are separated from each other and the second external power supply voltage is lower than the first external power supply voltage.

According to still another aspect of the present invention, there is provided a semiconductor integrated circuit comprising: a first internal power supply voltage down circuit which steps down a first external power supply voltage to produce a first internal power supply voltage; a second internal power supply voltage down circuit which steps down the first external power supply voltage to produce a second internal power supply voltage; an internal circuit to which the second internal power supply voltage is supplied; an output circuit to which a second external power supply voltage differing the first external power supply voltage is supplied and which is connected to the internal circuit; a voltage detecting circuit which, when the second external power supply voltage is equal to or lower than a decision voltage, outputs a first control signal and, when the second external power supply voltage is higher than the decision voltage, outputs a second control signal; a first input circuit which is activated by the first control signal and to which the first internal power supply voltage is supplied; and a second input circuit which is activated by the second control signal and to which the second internal power supply voltage is supplied, wherein the first and second external power supply voltages are separated from each other.

According to still another aspect of the present invention, there is provided a semiconductor integrated circuit comprising: an internal power supply voltage down circuit which steps down a first external power supply voltage to produce an internal power supply voltage; an internal circuit to which the internal power supply voltage is supplied; an output circuit to which a second external power supply voltage differing from the first external power supply voltage is supplied and which is connected to the internal circuit; a voltage detecting circuit which, when the second external power supply voltage is equal to or lower than a decision voltage, outputs a first control signal and, when the second external power supply voltage is higher than the decision voltage, outputs a second control signal; a first input circuit which is activated by the first control signal and to which the internal power supply voltage is supplied; and a second input circuit which is activated by the second control signal and to which the internal power supply voltage is supplied, wherein the first and second power supply voltages are separated from each other.

### BRIEF DESCRIPTION OF THE SEVERAL VIEWS OF THE DRAWING

FIG. 1 is a block diagram showing the basic configuration of embodiments of the invention;

FIG. 2 is a block diagram of a semiconductor integrated circuit according to a first embodiment of the present invention;

FIG. 3 is a block diagram of a semiconductor integrated circuit according to a second embodiment of the present invention;

FIG. 4 is a block diagram of a semiconductor integrated circuit according to an application of the second embodiment;

FIG. 5 shows a voltage detecting circuit; and

FIG. 6 is a block diagram of a semiconductor integrated circuit according to a modification of the second embodiment.

### DETAILED DESCRIPTION OF THE INVENTION

Hereinafter, referring to the accompanying drawings, embodiments of the invention will be explained in detail.

1. Outline

A semiconductor integrated circuit of the invention uses two external power supply voltages. One is a first external power supply voltage supplied from a first power terminal and the other is a second external power supply voltage supplied from a second power terminal.

The first and second external power supply voltages are separated from each other. The first external power supply voltage drives an input circuit and an internal circuit. The second external power supply voltage drives an output circuit.

The second external power supply voltage is lower than the first external power supply voltage.

The first external power supply voltage is supplied to the input circuit via an internal power supply voltage down circuit, not directly to the input circuit.

At this time, the first external power supply voltage is stepped down to the first internal power supply voltage (hereinafter, referred to as the input-circuit-only power supply voltage) by the internal power supply voltage down circuit. The input-circuit-only power supply voltage has almost the same voltage value as that of the second external power supply voltage.

The input-circuit-only power supply voltage is supplied to the input circuit.

As described above, the power supply voltage of the output circuit is low, which makes it possible to reduce the power consumption.

Moreover, since the input circuit and output circuit are driven by the corresponding power supply voltages separated from each other, the input circuit is not affected by the effect of noise caused by the output circuit.

Consequently, the power consumption of the input and output circuits can be reduced without allowing the input circuit to be affected by the effect of noise caused by the output circuit.

2. Embodiments

(1) Basic Configuration

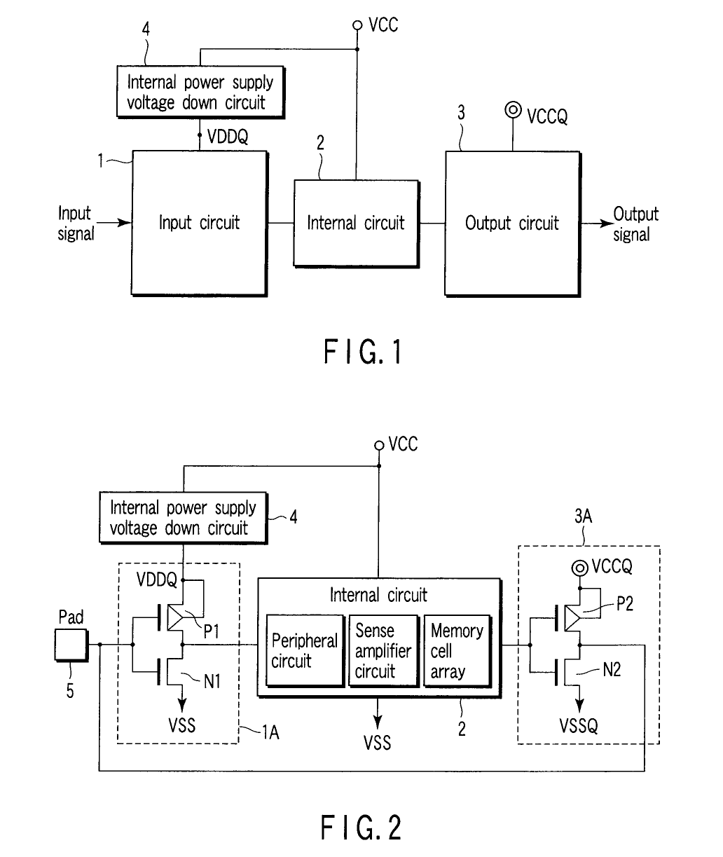

FIG. 1 is a block diagram showing the basic configuration of a semiconductor integrated circuit according to embodiments of the invention.

The semiconductor integrated circuit shown in FIG. 1 is driven by two external power supply voltages VCC, VCCQ separated from each other.

The external power supply voltage VCC is stepped down by an internal power supply voltage down circuit 4, which produces an input-circuit-only power supply voltage VDDQ. The input-circuit-only power supply voltage VDDQ is supplied to an input circuit 1.

The external power supply voltage VCC is also supplied to an internal circuit 2.

The external power supply voltage VCCQ is supplied to an output circuit 3. The external power supply voltage VCCQ is separated from the external power supply voltage VCC. To achieve lower power consumption, the voltage value of the external power supply voltage VCCQ is made lower than that of the power supply voltage VCC.

As described above, the power supply voltage of the input circuit 1 and that of the output circuit 3 are supplied from the separated power supplies.

Accordingly, noise caused by the output circuit 3 has no effect on the input circuit 1.

The power supply for the input circuit is shared with the internal circuit. Therefore, since a new power supply need not be provided for the input circuit only, an input-circuit-only power-supply pad or the like need not be added.

Consequently, the power consumption of the input and output circuits can be reduced without allowing the input circuit to be affected by noise caused by the output circuit.

Hereinafter, embodiments of the invention based on the basic configuration will be explained.

(2) First Embodiment

FIG. 2 shows a semiconductor integrated circuit according to a first embodiment of the invention.

The input circuit, such as an input buffer circuit 1A, is composed of a p-channel metal-oxide-semiconductor (MOS) transistor (hereinafter, referred to as a PMOS transistor) P1 and an n-channel MOS transistor (hereinafter, an NMOS transistor) N1.

The input buffer circuit 1A is connected to an input/output common pad 5 by an input terminal which connects the gate of the PMOS transistor P1 and that of the NMOS transistor N1. Moreover, the input buffer circuit 1A is connected to an internal circuit 2 by an output terminal which connects the drain of the PMOS transistor P1 and that of the NMOS transistor N1. Although the pad 5 is used for both input and output to reduce the number of external terminals in the first embodiment, an input pad and an output pad may be provided separately instead of the common pad 5.

The source of the PMOS transistor is connected to the internal power supply voltage down circuit 4. The source of the NMOS transistor N1 is connected to a connecting terminal to which ground voltage VSS is applied.

In the input buffer circuit 1A, a signal based on the input signal from the pad 5 is output to the internal circuit 2.

The internal circuit 2 is a circuit provided with a semiconductor memory, such as a NAND flash memory or a dynamic random access memory (DRAM). The internal circuit 2 is chiefly composed of a memory cell array section, a sense amplifier circuit, and a peripheral circuit which includes a row decoder circuit, a column decoder circuit, and an address buffer circuit.

The internal circuit 2 does processing on the basis of the signal from the input buffer circuit 1A and outputs the resulting data to an output buffer circuit 3A.

The output circuit, such as the output buffer circuit 3A, is composed of a PMOS transistor P2 and an NMOS transistor N2.

The output buffer circuit 3A is connected to the internal circuit 2 by the input terminal which connects the gate of the PMOS transistor P2 and that of the NMOS transistor N2. The data from the internal circuit 2 is input to the output buffer circuit 3A. An output terminal which connects the drain of the PMOS transistor P2 and that of the NMOS transistor N2 is connected to the pad 5.

The source of the PMOS transistor P2 is connected to a power supply voltage VCCQ. The source of the NMOS transistor N2 is connected to a ground terminal to which the ground voltage VSS is applied.

As power supply voltages which drive the above circuits, two external power supply voltages VCC, VCCQ are used. These two external power supply voltages are separated from each other and supplied to the circuits.

The external power supply voltage VCC is supplied to the internal circuit 2 and internal power supply voltage down circuit 4.

The external power supply voltage VCC supplied to the internal power supply voltage down circuit 4 is stepped down. An internal power supply voltage VDDQ for the input buffer circuit only is supplied from the source of the PMOS transistor P1 to the input buffer circuit 1A.

The external power supply voltage VCCQ is supplied from the source of the PMOS transistor P2 to the output buffer circuit 3A. The external power supply voltage VCCQ is set to a voltage lower than the external power supply voltage VCC to reduce the power consumption of the semiconductor integrated circuit.

As the power supply voltages, for example, 3V is used as the external power supply voltage VCC and 1.8V is used as the external power supply voltage VCCQ.

Therefore, a power supply voltage of 3V is supplied to the internal circuit 2 and internal power supply voltage down circuit 4.

A power supply voltage of 1.8V is supplied to the output buffer circuit 3A. The output buffer circuit 3A is driven with a circuit threshold voltage being the external power supply voltage VCCQ/2 (=0.9V).

An input-circuit-only internal power supply voltage VDDQ is supplied to the input buffer circuit 1A.

Generally, the input buffer circuit 1A is so designed that the circuit threshold voltage is equal to the input-circuit-only internal power supply voltage VDDQ/2. It is desirable that the circuit threshold voltage should be equal to that of the output buffer circuit 3A.

For this reason, the external power supply voltage VCC is stepped down to the input-circuit-only internal power supply voltage VDDQ (=1.8V), thereby driving the input buffer circuit 1A.

In the semiconductor integrated circuit of FIG. 2, a case where the internal power supply voltage down circuit 4 is not provided is considered.

In this case, the external power supply voltage VCC is supplied directly to the input buffer circuit 1A.

In general, the size of the PMOS transistor and NMOS transistor are so designed that the circuit threshold voltage of the CMOS inverter circuit in an input buffer circuit or the like is half the driving power supply voltage.

Therefore, the circuit threshold voltage of the input buffer circuit 1A is the external power supply voltage VCC/2 (=1.5V).

As described in the embodiment, the external power supply voltage VCCQ supplied to the output buffer circuit 3A is set at 1.8V to reduce the power consumption. Since the circuit threshold voltage of the output buffer circuit 3A is 0.9V, it is desirable that the circuit threshold voltage of the input buffer circuit 1A should also be set at 0.9V.

To set the circuit threshold voltage of the input buffer circuit 1A driven at the external voltage VCC (=3V) to 0.9V, the sizes of the NMOS transistor N1 have to be designed to be larger than those of the PMOS transistor P1.

With this method, however, the difference in response speed between the rising and falling in the input buffer circuit 1A is very large.

If the external power supply voltage VCC is set at 1.8V, the circuit threshold voltage of the input buffer circuit 1A can be set at the external power supply voltage VCC/2 (=0.9V), but the driving capability of the internal circuit 2 decreases.

Therefore, as described in the embodiment, the following is effective: the internal power supply voltage down circuit 4 steps down the external power supply voltage VCC (=3V) to the input-circuit-only internal power supply voltage VDDQ (=1.8V), thereby driving the input buffer circuit 1A.

By doing this, the circuit threshold voltage of the input buffer circuit 1A can be set easily to VDDQ/2 (=0.9V).

As described above, the power supply voltage of the input buffer circuit 1A is supplied from the external power supply voltage VCC via the internal power supply voltage down circuit 4. The power supply voltage of the output buffer circuit 3A is supplied from the external power supply voltage VCCQ.

Specifically, the input buffer circuit 1A and output buffer circuit 3A are driven by the two separated external power supply voltages. Consequently, the input buffer circuit 1A is not affected by the effect of noise caused by the output buffer circuit 3A.

Furthermore, since the external power supply voltage VCC that drives the internal circuit 2 is separated from the external power supply voltage VCCQ that drives the output buffer circuit 3A, the external power supply voltage VCC can be set to a voltage that prevents the driving capability of the internal circuit from decreasing and the external power supply voltage VCCQ can be set to a low voltage. Therefore, the power consumption of the output buffer circuit 3A can be reduced.

In addition, since the power supply voltage of the input buffer circuit 1A is obtained by stepping down the external power supply voltage VCC at the internal power supply voltage down circuit 4, a new power supply pad need not be provided.

Accordingly, the power consumption of the output circuit can be reduced without allowing the input circuit to be affected by the effect of noise caused by the output circuit.

(3) Second Embodiment

In a case where the internal circuit is particularly composed of a NAND flash memory, as the memory cell array section is miniaturized further, the internal circuit is required to offer the advantages of low-voltage driving and low power consumption.

In the second embodiment, an internal power supply voltage down circuit is provided not only in the input buffer circuit but also in the internal circuit. The following is an explanation of a semiconductor integrated circuit which steps down the external power supply voltage to a second internal power supply voltage and enables the internal circuit to cope with low-voltage driving and low power consumption.

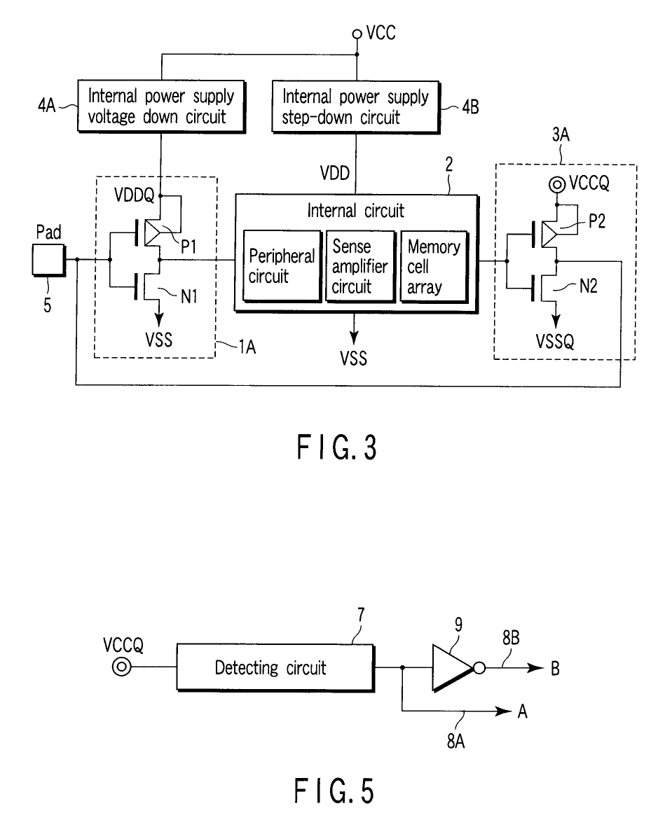

FIG. 3 shows a configuration of the semiconductor integrated circuit according to the second embodiment.

Each of the input buffer circuit 1A, internal circuit 2, and output buffer circuit 3A has the same circuit configuration as that in the first embodiment. In FIG. 3, the same elements are indicated by the same reference numerals and an explanation of them will be omitted.

Two external power supply voltages VCC, VCCQ are used as power supply voltages for driving the above circuits.

The external power supply voltage VCC is supplied to internal power supply voltage down circuits 4A, 4B.

The external power supply voltage VCC supplied to the internal power supply voltage down circuit 4A is stepped down to an input-circuit-only internal power supply voltage VDDQ. The input-circuit-only internal power supply voltage VDDQ is supplied to the input buffer circuit 1A.

The external power supply voltage VCC supplied to the internal power supply voltage down circuit 4B is stepped down to an internal power supply voltage VDD. The internal power supply voltage VDD is supplied to the internal circuit 2.

The external power supply voltage VCCQ is supplied to the output buffer circuit 3A.

For example, 3V is used as the external power supply voltage VCC and 1.8V is used as the external power supply voltage VCCQ.

The external power supply voltage VCC is stepped down by the internal power supply voltage down circuits 4A, 4B.

Therefore, the input-circuit-only internal power supply voltage VDDQ (=1.8V) obtained by stepping down the external power supply voltage VCC at the internal power supply voltage down circuit 4A is supplied to the input buffer circuit 1A.

The internal circuit 2 is supplied with, for example, the internal power supply voltage VDD (=2.7V) obtained by stepping down the external power supply voltage VCC at the internal power supply voltage down circuit 4B.

The external power supply voltage VCCQ (=1.8V) is supplied to the output buffer circuit 3A.

The input buffer circuit 1A and output buffer circuit 3A are driven by the corresponding power supply voltages separated from each other. Consequently, the input buffer circuit 1A is not affected by the effect of noise caused by the output buffer circuit 3A.

Since the external power supply voltage VCC can be stepped down by the internal power supply voltage down circuit 4B, the internal circuit 2 can be driven at low voltages.

As described above, the second embodiment can produce the effect of copying with the low-voltage driving and low power consumption of the internal circuit in addition to the effect of the first embodiment.

3. Application

In an application of the invention, the output circuit is compatible with a different power supply voltage specification. The following is an explanation of the circuit configuration and operation of a semiconductor integrated circuit which has two input circuits to meet the power supply voltage specification.

(a) Circuit Configuration

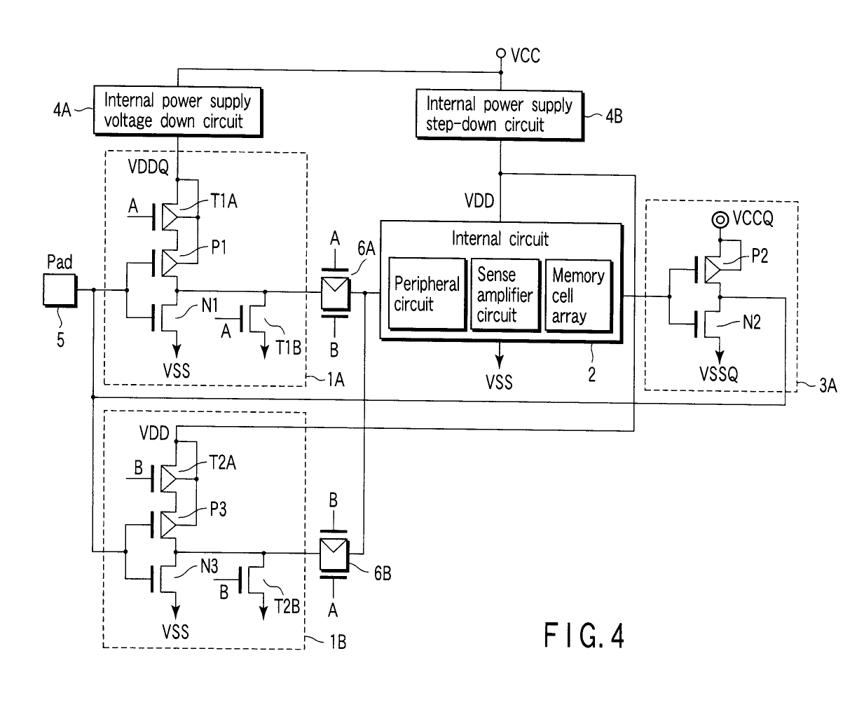

FIG. 4 shows a semiconductor integrated circuit according to the application.

A first input buffer circuit 1A not only has the configuration of the input buffer circuit 1A described in the first and second embodiments but also further includes MOS transistors T1A, T1B.

The source of the MOS transistor T1A is connected to the internal power supply voltage down circuit 4A. The drain of the MOS transistor T1A is connected to the source of the PMOS transistor P1.

The source of the MOS transistor T1B is connected to an output terminal composed of the drains of the PMOS and NMOS transistors P1, N1.

A second input buffer circuit 1B not only has the configuration of the input buffer circuit 1A described in the first and second embodiments but also further includes MOS transistors T2A, T2B.

The source of the MOS transistor T2A is connected to the internal power supply voltage down circuit 4B. The drain of the MOS transistor T2A is connected to the source of the PMOS transistor P3.

The source of the MOS transistor T2B is connected to an output terminal composed of the drains of the PMOS and NMOS transistors P3, N3.

The second buffer circuit 1B is driven by an internal power supply voltage VDD higher than that in the first buffer circuit 1A.

In the application, for example, the MOS transistors T1A, T2A are p-channel MOS transistors. The MOS transistors T1B, T2B are n-channel transistors.

Each of the internal circuit 2 and output buffer circuit 3A has the same internal configuration as that in the first and second embodiments.

The internal circuit 2 is connected to the first and second buffer circuits 1A, 1B via MOS switches 6A, 6B, respectively.

The output buffer circuit 3A has its input terminal connected to the internal circuit 2 and its output terminal connected to the pad 5. The output buffer circuit 3A is driven according to two power supply voltage specifications differing from each other.

As power supply voltages for driving the above circuits, the two external power supply voltages VCC, VCCQ are used.

The external power supply voltage VCC is supplied to the first internal power supply voltage down circuit 4A and to the second input power supply voltage down circuit 4B.

The external power supply voltage VCC supplied to the first internal power supply voltage down circuit 4A is stepped down to the internal power supply voltage VDDQ for the first input buffer circuit 1A only, which is then supplied to the first input buffer circuit 1A.

The external power supply voltage VCC supplied to the second internal power supply voltage down circuit 4B is stepped down to the internal circuit power supply voltage VDD, which is then supplied to the internal circuit 2 and the second input buffer circuit 1B.

The external power supply voltage VCCQ complies with two different power supply voltage specifications and is supplied to the output buffer circuit 3A.

FIG. 5 shows a voltage detecting circuit which selects either the input buffer circuit 1A or 1B to be activated according to the power supply voltage specification of the output buffer circuit 3A.

The voltage detecting circuit of FIG. 5 is supplied with the external power supply voltage VCCQ and causes a detecting circuit section 7 to determine the power supply voltage specification of the output buffer circuit 3A.

A signal based on the result of the determination is supplied not only to an output terminal 8A that outputs the signal as a control signal A but also via an inverter 9 to an output terminal 8B that outputs the signal as a control signal B.

The output terminal 8A is connected to the MOS transistors T1A, T1B and the output terminal 8B is connected to the MOS transistors T2A, T2B.

The output terminals 8A, 8B are also connected to MOS switches 6A, 6B.

Hereinafter, the operation of the semiconductor integrated circuit with the above configuration will be explained.

(b) Operation

As the power supply voltages for driving the semiconductor integrated circuit, for example, 3V is used as the external power supply voltage VCC and either 1.8 or 3V is used as the external power supply voltage VCCQ. The external power supply voltage VCC and the external power supply voltage VCCQ are supplied to the circuits in such a manner that they are separated from each other.

The external power supply voltage VCC is stepped down by the internal power supply voltage down circuits 4A, 4B.

The external power supply voltage VCC is stepped down to the input-circuit-only power supply voltage VDDQ (=1.8V) by the internal power supply voltage down circuit 4A, which is then supplied to the first buffer circuit. Moreover, the external power supply voltage VCC is stepped down to the internal power supply voltage VDD (=2.7V) by the internal circuit 4B, which is then supplied to the second input buffer circuit 1B and internal circuit 2.

In addition, either 1.8 or 3V is supplied as the external power supply voltage VCCQ to the output buffer circuit 3A according to the power supply voltage specification.

In the voltage detecting circuit of FIG. 5, a decision voltage used to determine whether the external power supply voltage VCCQ is higher or lower is set at, for example, 2.2V. Using the decision voltage as a reference, the control signals A, B are output to the first and second input buffer circuits 1A, 1B and MOS switches 6A, 6B.

When the external power supply voltage VCCQ is equal to or lower than 2.2V, the detecting circuit section 7 outputs, for example a low-level signal, with the result that control signal A goes low and control signal B via the inverter 9 goes high. When the external power supply voltage VCCQ is higher than 2.2V, the detecting circuit section 7 outputs a high-level signal, with the result that control signal A goes high and control signal B goes low.

When the external power supply voltage VCCQ is at 1.8V, the external power supply voltage VCCQ of 1.8V is supplied to the output buffer 3A and detecting circuit section 7.

Therefore, the detecting circuit section 7 determines that the external power supply voltage VCCQ is equal to or lower than 2.2V and therefore the output buffer circuit 3A deals with the external power supply voltage VCCQ of 1.8V according to the power supply voltage specification.

As a result, the low control signal A and the high control signal B are output at the terminals 8A, 8B, respectively.

In the first input buffer circuit 1A, the input of the low control signal A turns on the PMOS transistor T1A and turns off the NMOS transistor T1B.

Accordingly, the internal power supply voltage down circuit 4A supplies the input-buffer-circuit-only internal voltage VDDQ (=1.8V) to the first input buffer circuit 1A, which is thus activated.

The MOS switch 6A connected to the first input buffer circuit 1A is turned on by control signal A and control signal B, which causes the signal from the first input buffer circuit 1A to be output to the internal circuit 2.

In the second buffer circuit 1B, the input of the high control signal turns off the PMOS transistor T2A and turns on the NMOS transistor T2B.

Therefore, since the internal power supply voltage VDD is cut off by the PMOS transistor T2A when that transistor is off, the second buffer circuit 1B is deactivated. To prevent a malfunction caused by stray capacitance at the output node, the second buffer circuit 1B is grounded by the NMOS transistor T2B when that transistor is on.

Moreover, since the MOS switch 6B is also off, the second input buffer circuit 1B is electrically isolated from the internal circuit 2.

The data based on the signal from the first input buffer circuit 1A is output from the internal circuit 2 to the output buffer circuit 3A.

The output signal based on the data from the internal circuit 2 is output from the output buffer circuit 3A via the pad 5 to the outside.

When the external power supply voltage VCCQ is at 3V, the eternal power supply voltage VCCQ of 3V is supplied to the output buffer circuit 3A and detecting circuit section 7.

Therefore, the detecting circuit section 7 determines that the external power supply voltage VCCQ is higher than 2.2V and therefore the output buffer circuit 3A deals with the external power supply voltage VCCQ of 3V according to the power supply voltage specification.

As a result, the high level control signal A and low control signal B are output at the terminals 8A, 8B, respectively.

In the first input buffer circuit 1A, the high level control signal A turns off the PMOS transistor T1A and turns on the NMOS transistor T1B.

Therefore, since the internal-circuit-only power supply voltage VDDQ is cut off by the PMOS transistor T1A when that transistor is off, the first buffer circuit 1A is deactivated.

To prevent a malfunction caused by stray capacitance at the output node, the first buffer circuit 1A is grounded by the NMOS transistor T1B when that transistor is on.

Furthermore, since the MOS switch 6A connected to the first input buffer circuit 1A turns off, the first input buffer circuit 1A is electrically isolated from the internal circuit 2.

In the second input buffer circuit 1B, the input of the low control signal B turns on the PMOS transistor T2A and turns off the NMOS transistor T2B.

Accordingly, the internal power supply voltage down circuit 4B supplies the internal power supply voltage VDDQ (=2.7V) to the second input buffer circuit 1B, which is thus activated.

Moreover, since the MOS switch 6B connected to the second input buffer circuit 1B turns on, the signal from the second input buffer circuit 1B is output to the internal circuit 2.

The data based on the signal from the second input buffer circuit 1B is output from the internal circuit 2 to the output buffer circuit 3A.

Thereafter, an output signal based on the data from the internal circuit 2 is output from the output buffer circuit 3A via the pad 5 to the outside.

While in the application, switching between the first and second input buffer circuits 1A, 1B has been done using the voltage detecting circuit of FIG. 5, the invention is not limited to the switching method. Another suitable method may be used, provided that one of the first and second input buffer circuits is activated and the other is deactivated.

For example, in the wiring process in the wafer processing, aluminum wires are connected to the external power supply voltage VCC or the ground voltage VSS of the first and second input buffer circuits 1A, 1B. With this connection, the input buffer circuits 1A, 1B may be deactivated according to the magnitude of the external power supply voltage VCCQ, thereby switching between the input buffer circuits.

Specifically, when the external power supply voltage VCCQ is at 1.8V according to the power supply voltage specification, the aluminum wire connected to the control signal A terminal of the MOS transistors T1A, T1B is connected to the ground voltage VSS terminal. Moreover, the aluminum wire connected to the control signal B terminal of the MOS transistors T2A, T2B is connected to the external power supply voltage VCC terminal.

When the external power supply voltage VCCQ is at 3V according to the power supply voltage specification, the aluminum wire connected to the control signal A terminal is connected to the external power supply voltage VCC terminal and the aluminum wire connected to the control signal B terminal is connected to the ground voltage VSS terminal.

Furthermore, for example, in the bonding process, the bonding pad previously provided in the semiconductor integrated circuit is connected to the external power supply voltage VCC terminal of the package or the ground voltage VSS terminal with a wire.

With this connection, the input buffer circuits 1A, 1B may be deactivated according to the magnitude of the external power supply voltage VCCQ, thereby switching between the input buffer circuits.

Specifically, when the external power supply voltage VCCQ is at 1.8V according to the power supply voltage specification, the pad provided at the control signal A terminal of the MOS transistors T1A, T1B is connected to the ground voltage VSS terminal with a wire. Moreover, the pad provided at the control signal B terminal of the MOS transistors T2A, T2B is connected to the external power supply voltage VCC terminal with a wire.

When the external power supply voltage VCCQ is at 3V according to the power supply voltage specification, the pad provided at the control signal A terminal is connected to the external power supply voltage VCC terminal with a wire and the pad provided at the control signal B terminal is connected to the ground voltage VSS terminal with a wire.

Furthermore, a read-only Memory (ROM) is provided in the circuit and “1” and “0” are stored in advance as data corresponding to the magnitude of the external power supply voltage VCCQ. On the basis of this, switching between the first and second input buffer circuits may be done.

As described above, in the semiconductor integrated circuit of the application, even when two input circuits which cope with the difference between the power supply voltage specifications of the output circuits are provided, the power consumption of the input and output circuits can be reduced without allowing the first and second input circuit to be affected by the effect of noise caused by the output circuit.

Furthermore, two products differing in the power supply voltage specification of the external power supply voltage VCCQ can be realized on the same chip.

While in the application, the output circuit has been compatible with two power supply voltages, it may be designed to be compatible with three or more power supply voltages.

In this case, the configuration is such that an input circuit for a circuit threshold voltage corresponding to each of the power supply voltages is provided and switching between the input circuits is done according to the power supply voltage of the output circuit.

4. Modification

In a modification of the embodiment, the output buffer circuit is compatible with two different power supply voltage specifications as in the application. There are provided two input buffer circuits differing in circuit threshold voltage. In the modification, however, a case where the two input buffer circuits are driven by the same power supply voltage as that of the internal circuit will be explained.

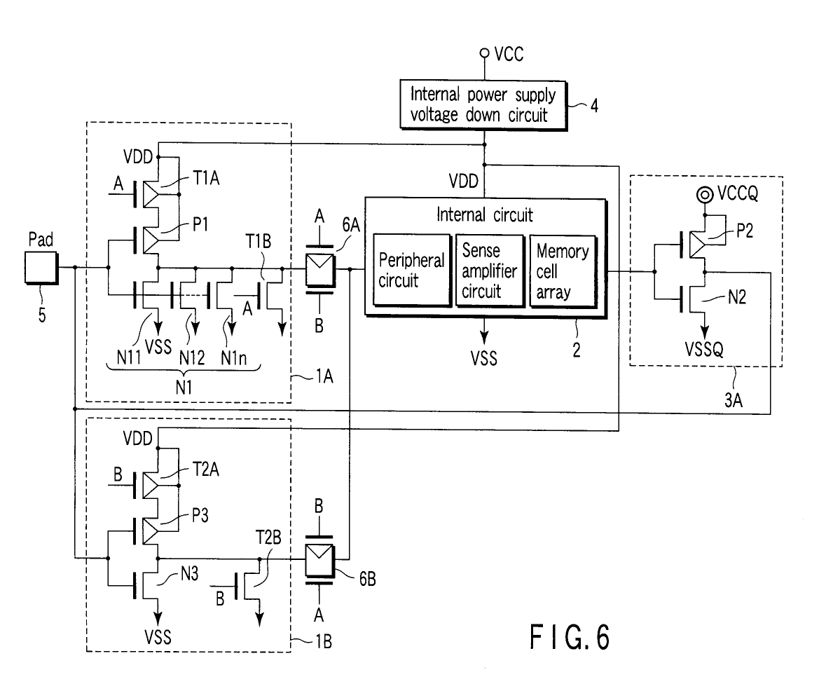

FIG. 6 shows a semiconductor integrated circuit according to the modification.

The first input buffer circuit 1A has basically the same configuration as that of the application, expect that an NMOS transistor N1 of the modification is composed of a plurality of NMOS transistors N11 to N1n connected in parallel.

Each of the second input buffer circuit 1B, internal circuit 2, and output buffer circuit 3A has the same configuration as that in the application. The same elements are indicated by the same reference numerals and an explanation of them will be omitted.

The voltage detecting circuit has the same configuration as shown in FIG. 5.

The internal power supply voltage down circuit 4 is connected to the first input buffer circuit 1A, second input buffer circuit 1B, and internal circuit 2.

As power supply voltages for driving the above circuits, the following two power supply voltages are used: an external power supply voltage VCC and an external power supply voltage VCCQ.

The power supply voltage VCC is stepped down to an internal power supply voltage VDD by the internal power supply voltage down circuit 4.

The internal power supply voltage VDD is supplied to the first and second input buffer circuits 1A, 1B and internal circuit 2. That is, the first and second input buffer circuits 1A, 1B and internal circuit 2 are driven by the same power supply voltage.

The external power supply voltage VCCQ, which conforms to two different power supply voltage specifications, is supplied to the output buffer circuit 3A.

For example, 3V is used as the external power supply voltage VCC and either 1.8 or 3V is used as the external power supply voltage VCCQ according to the power supply voltage specification.

The external power supply voltage VCC is stepped down to the internal power supply voltage VDD (=2.7V) by the internal power supply voltage down circuit 4. The internal power supply voltage VDD is supplied to the first and second input buffer circuits 1A, 1B and internal circuit 2.

Whether the power supply voltage specification of the external power supply voltage VCCQ is for 3 or 1.8V is determined by the voltage detecting circuit of FIG. 5 in the same manner as in the application.

When the output buffer circuit 3A is driven by the external power supply voltage VCCQ (=1.8V), the first input buffer circuit 1A is activated and the second input buffer circuit 1B is deactivated.

At this time, the circuit threshold voltage of the output buffer circuit 3A is the external power supply voltage VCCQ/2 (=0.9V).

The internal power supply voltage VDD (=2.7V) is supplied to the first input buffer circuit 1A, which is driven at this voltage.

To set the circuit threshold voltage of the first input buffer circuit 1A driven at the power supply voltage to 0.9V, the size of the NMOS transistor N1 are designed to be larger than those of the PMOS transistors P1, T1A.

A method of increasing the size of the NMOS transistor N1 is to make the NMOS transistor N1 out of a plurality of NMOS transistors N11 to N1n connected in parallel. This achieves a method of increasing the effective size of the NMOS transistor N1.

When the external power supply voltage VCC is at 3V, the second input buffer circuit 1B is activated.

At this time, the circuit threshold voltage of the output buffer circuit 3A is the external power supply voltage VCCQ/2 (=1.5V).

The internal power supply voltage of 2.7V is supplied to the second input buffer circuit 1B. To set the circuit threshold voltage of the second input buffer circuit 1B to 1.5V, the size of the PMOS transistor P3 and PMOS transistor T2A are designed to be larger than those of the NMOS transistor N3.

As described above, the first and second input buffer circuits 1A, 1B are driven by the power supply voltage VDD shared with the internal circuit 2. Therefore, the circuit threshold voltage of the first and second input buffer circuits 1A, 1B can be made equal to the circuit threshold voltage of the output buffer circuit 3A by adjusting the size of the PMOS transistor and NMOS transistor constituting the input buffer circuits 1A, 1B.

In this case, too, the power consumption of the input and output circuits can be reduced without allowing the input circuit to be affected by the effect of noise caused by the output circuit.

The invention has the following advantage in addition to the advantages described in the first and second embodiments, application, and modification.

The invention is characterized in that the internal power supply voltage VDDQ produced at the internal power supply voltage down circuit 4 in the first embodiment and the first internal power supply voltage VDDQ produced at the first internal power supply voltage down circuit 4A in the second embodiment and application are almost the same voltage value as that of the second external power supply voltage VCCQ.

5. Others

According to embodiments of the present invention, the power consumption of the input and output circuits can be reduced without allowing the input circuit to be affected by the effect of noise caused by the output circuit.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor integrated circuit comprising:
an internal power supply voltage down circuit which steps down a first external power supply voltage to produce an internal power supply voltage;
an input circuit to which the internal power supply voltage is supplied;
an internal circuit to which the first external power supply voltage is supplied and which is connected to the input circuit; and
an output circuit to which a second external power supply voltage differing from the first external power supply voltage is supplied and which is connected to the internal circuit,
wherein the first and second external power supply voltages are separated from each other and the second external power supply voltage is lower than the first external power supply voltage.

2. The semiconductor integrated circuit according to claim 1, wherein the internal power supply voltage and the second external power supply voltage are the same voltage value.

3. The semiconductor integrated circuit according to claim 1, wherein the internal circuit is a semiconductor memory.

4. The semiconductor integrated circuit according to claim 1, further comprising an input-output common pad connected to the input circuit and the output circuit.

5. A semiconductor integrated circuit comprising:
a first internal power supply voltage down circuit which steps down a first external power supply voltage to produce a first internal power supply voltage;
an input circuit to which the first internal power supply voltage is supplied;
a second internal power supply voltage down circuit which steps down the first external power supply voltage to produce a second internal power supply voltage;
an internal circuit to which the second internal power supply voltage is supplied and which is connected to the input circuit; and
an output circuit to which a second external power supply voltage differing from the first external power supply voltage is supplied and which is connected to the internal circuit,
wherein the first and second external power supply voltages are separated from each other and the second external power supply voltage is lower than the first external power supply voltage.

6. The semiconductor integrated circuit according to claim 5, wherein the first internal power supply voltage and the second external power supply voltage is the same voltage value.

7. The semiconductor integrated circuit according to claim 5, wherein the first internal power supply voltage is lower than the second internal power supply voltage.

8. The semiconductor integrated circuit according to claim 5, wherein the internal circuit is a semiconductor memory.

9. A semiconductor integrated circuit comprising:
a first internal power supply voltage down circuit which steps down a first external power supply voltage to produce a first internal power supply voltage;
a second internal power supply voltage down circuit which steps down the first external power supply voltage to produce a second internal power supply voltage;
an internal circuit to which the second internal power supply voltage is supplied;
an output circuit to which a second external power supply voltage differing the first external power supply voltage is supplied and which is connected to the internal circuit;
a voltage detecting circuit which, when the second external power supply voltage is equal to or lower than a decision voltage, outputs a first control signal and, when the second external power supply voltage is higher than the decision voltage, outputs a second control signal;
a first input circuit which is activated by the first control signal and to which the first internal power supply voltage is supplied; and
a second input circuit which is activated by the second control signal and to which the second internal power supply voltage is supplied,
wherein the first and second external power supply voltages are separated from each other.

10. The semiconductor integrated circuit according to claim 9, wherein the second external power supply voltage is lower than the first external power supply voltage.

11. The semiconductor integrated circuit according to claim 9, wherein the first internal power supply voltage and the second external power supply voltage is the same voltage value.

12. The semiconductor integrated circuit according to claim 9, wherein the first internal power supply voltage is lower than the second internal power supply voltage.

13. The semiconductor integrated circuit according to claim 9, wherein the circuit threshold voltage of the first input circuit is lower than that of the second input circuit.

14. The semiconductor integrated circuit according to claim 9, wherein the internal circuit is a semiconductor memory.

15. A semiconductor integrated circuit comprising:
an internal power supply voltage down circuit which steps down a first external power supply voltage to produce an internal power supply voltage;
an internal circuit to which the internal power supply voltage is supplied;
an output circuit to which a second external power supply voltage differing from the first external power supply voltage is supplied and which is connected to the internal circuit;
a voltage detecting circuit which, when the second external power supply voltage is equal to or lower than a decision voltage, outputs a first control signal and, when the second external power supply voltage is higher than the decision voltage, outputs a second control signal;
a first input circuit which is activated by the first control signal and to which the internal power supply voltage is supplied; and
a second input circuit which is activated by the second control signal and to which the internal power supply voltage is supplied,
wherein the first and second power supply voltages are separated from each other.

16. The semiconductor integrated circuit according to claim 15, wherein the second external power supply voltage is lower than the first external power supply voltage.

17. The semiconductor integrated circuit according to claim 15, wherein the circuit threshold voltage of the first input circuit is lower than that of the second input circuit.

18. The semiconductor integrated circuit according to claim 15, wherein the first input circuit is composed of a p-type MOS transistor and a n-type MOS transistor, a size of the n-type MOS transistor is larger than a size of p-type MOS transistor.

19. The semiconductor integrated circuit according to claim 15, wherein the second input circuit is composed of a p-type MOS transistor and a n-type MOS transistor, a size of the p-type MOS transistor is larger than a size of the n-type MOS transistor.

20. The semiconductor integrated circuit according to claim 15, wherein the internal circuit is a semiconductor memory.
